(19) United States
(12) Patent Application Publication
(10) Pub. No.: US 2017/0200659 A1
(43) Pub. Date: Jul. 13, 2017

(54) POROUS UNDERFILL ENABLING REWORK

(71) Applicant: International Business Machines Corporation, Armonk, NY (US)

(72) Inventors: Michael Gaynes, Vestal, NY (US); Jeffrey Gelorme, Burlington, CT (US); Thomas Brunschwiler, Thalwil (CH); Brian Burg, Zurich (CH); Gerd Schlottig, Uitikon (CH); Jonas Zuercher, Chur (CH)

(21) Appl. No.: 14/990,902

(22) Filed: Jan. 8, 2016

(51) Int. Cl. H01L 21/66; H01L 23/29; H01L 21/56; H01L 23/31; H01L 25/00; H01L 23/00

(52) U.S. Cl. CPC H01L 22/26; H01L 25/50; H01L 24/81; H01L 21/561; H01L 23/3185; H01L 21/563; H01L 23/295

(57) ABSTRACT

The disclosure generally relates to methods for manufacturing a filled gap region or cavity between two surfaces forming a device microchip. In one embodiment, the cavity results from two surfaces, for example, a PCB and a chip or two chips. More specifically, the disclosure relates to a method of manufacture and the resulting apparatus having porous underfill to enable rework of the electrical interconnects of a microchip on a multi-chip module. In one embodiment, the disclosure builds on the thermal underfill concept and achieves high thermal conductivity by the use of alumina fillers. Alternatively, other material such as silica filler particles may be selected to render the underfill a poor thermal conductive. In one embodiment, the disclose is concerned with reworkability of the material.

### BACKGROUND

Field

The disclosure generally relates to methods for manufacturing a filled gap region or cavity between two surfaces forming a device microchip. In one embodiment, the cavity results from two surfaces, e.g. a PCB and a chip or two chips. More specifically, the disclosure relates to a method of manufacture and the resulting apparatus having porous underfill to enable rework of the electrical interconnects of a microchip on a multi-chip module.

Description of Related Art

In modern electronic devices, substantial gains in performance are continuously achieved by means of circuit miniaturization and by the integration of single-package multi-functional chips. The scalability and performance of such electronic devices are related to their ability to dissipate heat. In typical flip-chip arrangements, one integrated circuit (IC) surface is used for heat removal through a heat sink, while the other for power delivery and data communication. Power and communication is provided throughout solder balls attached to electrical pads on the IC chip that are reflowed and coupled to the main circuit board.

To minimize mechanical stress in the solder balls and to protect them electrically, mechanically, and chemically, the gap region between an IC chip and board, created due to the presence of solder balls, is conventionally filled with electrically non-conductive materials known as underfills. Current efforts towards 3D chip integration, with solder balls as electrical connection between silicon dies, demand high thermally conductive underfills to efficiently dissipate the heat of lower dies to the heat removal embodiment attached at the chip stack backside. Some flip-chip on-board applications do also benefit from efficient heat dissipation from the semiconductor die into the board. Hence, thermal underfills between semiconductor and board are desirable. Additionally, electric joints between circuit board pads and metallic coatings at chips should be flexibly produced.

Conventional mechanical underfills may consist of a curable matrix (e.g. epoxy resin) loaded with silica fillers, which fillers have a similar thermal expansion coefficient (CTE) to that of the silicon. Currently, the requirement of matching CTE with the solder balls dictates the type, and volumetric fill of fillers to be employed in a given underfill. For thermal underfills, the thermal conductivity of filler materials which are used to increase the thermal contact and enhance heat dissipation between connected surfaces should be high. Therefore, Al2O3, AlN, BN or other dielectric materials are used.

Conventionally, an underfill material can be dispensed into a gap between chips or a flip-chip and a substrate by injecting the filling material along the lateral sides of the gap. The underfill then flows into the gap by capillary action and fillers the space between chip and board.

### SUMMARY

The disclosed embodiments relate to a multi-chip module (MCM) and method of manufacture thereof which enables rework of one or more microchips on the MCM after the test and burn-in period. In one embodiment, the disclosure relates to a porous underfill to enable rework of a microchip.

In one embodiment, the disclosure builds on the thermal underfill concept and achieves high thermal conductivity by the use of alumina fillers. Alternatively, other material such as silica filler particles may be selected to render the underfill a poor thermal conductive. In one embodiment, the disclose is concerned with reworkability of the material.

An exemplary method to form multi-chip module (MC) with porous underfill enabling rework, comprising the steps of: attaching a plurality of microchips on to a substrate using a plurality of solderballs, the solderballs forming a plurality of gaps between the microchip and the substrate; filling the plurality of gaps between the chip and the substrate with a porous composition comprising a slurry of polymer material, filler micro-particles, resin and solvent, wherein the step of filling the plurality of gaps is selected from one or more centrifugal-assisted filling, capillary or pre-apply; substantially evaporating the solvent from the gaps at an evaporating solvent temperature; for a first of the plurality of microchips, forming a mechanical neck by substantially evaporating the solvent from the gaps to form a capillary bridge, wherein the mechanical neck comprises phenoxy resin; testing the first microchip to detect operation failure; if operation failure detected, removing the first microchip with one of shearing the first microchip after localized heating of the first microchip or by chemically dissolving the mechanical neck between the first microchip and the substrate, reattaching a second microchip in the place of the first microchip after preparing the attachment site; and if no operation failure is detected, adhesive backfilling the underfill using one or more epoxy adhesive having a final cure agent; wherein the polymer material is selected from the group consisting of: polyimides, bismaleimides, epoxies and cyanate esters; wherein the porous composition further comprises one or more of an epoxy and an initial cure agent requiring higher cure temperature and cure time relative to the evaporating solvent temperature, the cure agent to cure during a backfilling underfill step.

In one embodiment, the disclosed methods also work for capillary and pre-applied underfills, not requiring sequential filling with the centrifuge. The process may start from a dispersion of solvent, resin, hardener, filler particles. The solvent should not evaporate at the filling temperature, but evaporation may take place at elevated temperature after the filling of the cavity. The filler particles would rearrange and polymer necks would interconnect them.

### BRIEF DESCRIPTION OF THE DRAWINGS

These and other embodiments of the disclosure will be discussed with reference to the following exemplary and non-limiting illustrations, in which like elements are numbered similarly, and where:

FIG. 1 schematically illustrates a first step in forming a filled cavity between spaced surfaces;

FIG. 2 schematically illustrates a second step in forming a filled cavity between spaced surfaces in which the chip is brought to close proximity of the board;

FIG. 3 schematically illustrates a third step in forming a filled cavity between spaced surfaces in which the chip and the board are in contact through microparticles;

FIG. 4 schematically illustrates a fourth step in forming a filled cavity between spaced surfaces in which some of the solvent is removed;

FIG. 5 schematically illustrates a first step in forming a neck between the chip and the board;

FIG. 6 shows a detailed view of the embodiments of FIGS. 1-5 for illustrating a necking process;

FIG. 7 schematically shows a porous underfill according to one embodiment of the disclosure;

FIGS. 8A-8D show magnified compositions of polymer used for neck material according to one embodiment of the disclosure;

FIG. 9A schematically illustrates a side view of an exemplary MCM;

FIG. 9B schematically illustrates a top view of an exemplary MCM; and

FIG. 10 schematically illustrates the process steps of an exemplary embodiment of the disclosure.

### DETAILED DESCRIPTION

Certain embodiments of the presented method for manufacturing a filled cavity between spaced surfaces may comprise individual or combined features, method steps or aspects as mentioned above or below with respect to exemplary embodiments. In the following, embodiments of methods and devices relating to the manufacture of fillings in a cavity are described with reference to the enclosed drawings. Like or functionally like elements in the drawings have been allotted the same reference characters, if not otherwise indicated.

The term “filler material” refers to a viscous material or material composition that can be dispersed in a cavity or gap. One can also refer to a filling agent, a paste, or a liquid. The viscous filler material essentially forms a closed flow front that expands with the volume of the material. The filling material may include a carrier fluid having suspended particles. Hence, the material composition can have a plurality of ingredients having different phases, e.g. liquid and/or solid particles.

As used herein, the term “spacer elements” refers to objects of same or similar spatial extension that are suitable for spacing or separating two surfaces at a distance corresponding to their spatial dimension. “Spacer particles” can essentially be of any shape but should have the same “diameter” within a reasonable tolerance. The spacer particles can be small pieces or bits of a solid material.

A “cavity” or gap between two surfaces, e.g. in a chip stack is a volume between two surfaces that are spaced with respect to each other. The volume usually has a much larger lateral extension than its height, width, or thickness. The cavity can have lateral sides that are open. However, the sides can be limited by side-walls or other structural elements as well.

The term “holding between” is intended to include that two elements are attached to each other, and adhesive forces hold them essentially in place. For example, the spacer particle is held between the two surfaces and serves as a spacing means that is sandwiched between the surfaces.

It is understood that, in the following, only sections or parts of cavity structures are shown. In actual embodiments the depicted structures would extend through the paper plane and continue further than shown in the schematic drawings. By approaching the first and second surfaces, or in other words, bringing the two surfaces together, a space gap or cavity is formed. The distance between the surfaces in their end position is defined by the size of the spacer elements that arrange between the surfaces and, for example, are held or locked between the surfaces. In the process of approaching or bringing the surfaces together, the filling material which can be a viscous material is deformed or squeezed and distributes itself in the narrowing gap. A plurality of spacer elements can touch the two surfaces.

The disclosed embodiments generally relate to a method for manufacturing re-workable multi-chip modules (MCMs). MCMs are used to package multiple integrated circuit (IC) dies in close proximity with large wire count on a single substrate. Rework of individual die on the MCM after test and burn-in is important especially for many, low-yield or expensive components. In the past, manufacturers have used ceramic modules with low CTE mismatch to the silicon die. This allowed the integration of die without the need of underfills and hence, enabled rework.

Manufacturers are now transitioning to organic substrates which creates a large CTE mismatch with the silicon die. Hence, underfills are required not only for operation, but also for the test and burn-in sequence to prevent fracture of solder balls or the back-end-of the line (BEOL) layers. Current underfills cannot be removed and result in non-reworkable die attach. Hence, manufacturers have transitioned to single-chip-modules (SCMs) with large spatial distance between components and limited wiring capabilities. It is desirable to transition back to MCM having organic carriers. An embodiment of the disclosure provides means to enable rework of a die which survives test and burn-in conditions so as to be used as an MCM with an organic substrate.

Conventional solutions include grinding and formulating thermally and chemically cleavable underfills. Individual die which were underfilled may be ground off from the MCM after a fail is detected. The procedure may be difficult for an array arrangement of die and may leave residues on the substrate, thereby creating difficulties for the subsequent attachment of the replacement microchip. In addition, the grinding or milling process must be controlled very accurately to remove the die without damaging the substrate which may have random warpage due to the inherent variability in the lamination and build-up processing. Such variations may be due to fabrication of the organic substrate.

Thermally reversible or cleavable underfills have been demonstrated. Here, the cross-links of certain polymers can be reversed or weakened by thermal exposure. By exposure to heat, the polymer softens above a certain temperature which allows the removal of an individual die. However, the limited selection of such specialized materials may compromise the adhesion and performance of the underfill. Such thermally softened materials are more prone to thermal degradation at temperatures below the softening or rework temperature. Therefore, this class of material does not perform well in the long term environmental stress testing required for qualification and acceptance.

Chemically cleavable underfills have been formulated to overcome the sensitivity to thermal degradation. However, these have been shown to be sensitive to humidity degradation and thus unable to survive required Joint Electronic Devices Engineering Counsel preconditioning requirements.

In certain embodiments, the disclosure relates to use of the sequential underfill process to yield high thermal conductive underfills by capillary bridging. In one embodiment, the disclosure relates to a formulation of a temporary porous underfill by sequential filling method including capillary bridging of a matrix material to secure the chip and the electrical interconnects during test and burn-in. The connection allows rework where electrical failure is detected. It may be possible to shear or torque the die off the MCM at elevated temperature (temperature above solder liquids) with acceptable forces which can be defined or controlled by the polymer neck diameter between particles.

Alternatively, the partial and porous underfill that provides structural polymer necks between particles can be dissolved by injecting a solvent into the pores of a single die. The pores allow the local access of the solvent to perform dissolution step in a short time period.

In one application, a slurry comprising particle, polymer and solvent is introduced in the gaps between the die and the substrate. The solvent may be removed through controlled evaporation. As the solvent evaporates, the polymer concentrates at the contact points between particles and forms a bridge or joining neck that provides adequate structural reinforcement of the solder joints so that downstream processing and testing can be completed without damaging the solder connections or the dielectric layers on the active side of the die.

The polymer necking material may be selected from polyimides, bismaleimides, epoxies and cyanate esters or a combination thereof. All of which may be compatible with a final capillary underfill formation and responsive to a final cure. An epoxy without a cure agent or only a small amount of cure agent or a cure agent that requires long time at high temperature to activate may be used to form the necks. A final epoxy with cure agent may be flowed into the porous network. The curing agent of the second, flow-able epoxy should be sufficient to accomplish a final cure of the necks as needed.

In an alternative embodiment, a thermoplastic polymer can be used to create the necks. The choice of a thermoplastic neck avoids the challenge of having to control the partial/latent cure of a thermosetting material. Therefore, it enables a controllable and predictable process for chip removal either with heat alone or with solvation of the thermoplastic neck before heating. In one exemplary embodiment, the thermoplastic neck may comprise phenoxy resin which may easily dissolve in a common solvent including methyl ethyl ketone (MEK) or acetone.

After porous network of particles and adjoining polymer necks are formed, the solder joints and inter layer dielectric may be mechanically and environmentally protected through electrical testing. Chips that fail electrical testing may be easily removed with a typical chip rework tool that provides high localized heating to the target chip. Heating may be a combination of conduction heating through the substrate or infrared heating. In one embodiment, hot gas may be flowed over the region. In still another embodiment, conductive heating may be directed to the chip.

When the chip reaches the solder melt temperatures, the chip may be removed either by tensile lifting or mild torque. In the case of tensile lifting, the head of the rework tool contacts the backside of the chip and vacuum is applied to mechanically link the chip to the vacuum pick tube. If the tensile force is too great to lift the chip because of the chip size and strength of the porous and polymer necked underfill, the vacuum pick tube can be modified to have vertical, downward extending features that at first clear the vertical sidewall of the chip and then contact the vertical sidewall of the chip when rotated a few degrees and therefore apply torque and a shear force to help break the porous particle matrix connections.

After the chip has been removed, the chip site on the substrate needs to be cleaned and prepared for the placement and solder attach of the known good die (i.e., replacement die). Since the polymer necks have only been at most partially cured (or not at all cured), a common solvent may be effective at removing the particles and polymer connecting necks. The solvent can be contained, if needed, to the reworked chip site area by using a temporary damming material that surrounds the perimeter of the chip site. Any residual solder may require leveling and resetting which may follow common accepted practices. Such practices may include drawing away excess solder in a porous solderable surface such as a porous copper block or textured copper foil as is used in the fabrication of printed circuit boards. U.S. Pat. No. 5,909,838, which is incorporated herein in its entirety for background information, provides exemplary techniques for leveling and resetting. Reference is also made to U.S. Patent Publication No. 20150249022 A1 (filed by certain inventors named herein and subject to assignment to the same entity as the instant application) which is incorporated herein in its entirety for background information.

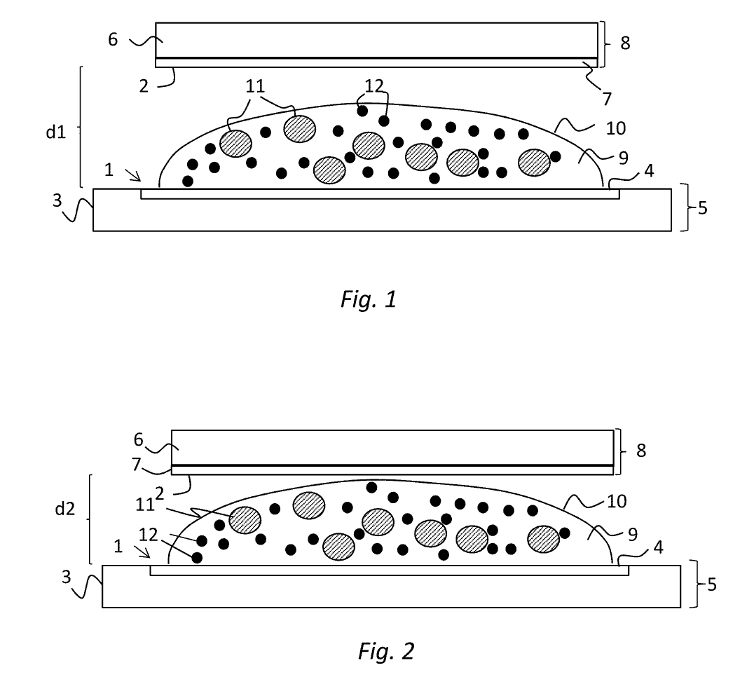

FIGS. 1-5 show schematic diagrams of the steps involved in the manufacture of a filled cavity or gap between two surfaces. Specifically FIG. 1 schematically shows a die, first surface 1 and second surface 2. First surface 1 and second surface 2 can be part of laminates, chips, dies, circuit boards or the like. In the embodiment shown in FIG. 1, first surface 1 is part of laminate 3 having a metallic pad 4. In the orientation of FIG. 1, the lower surface structure can be part of board 5, which can be a dielectric board, and is provided with pads 4. The upper surface structure is, for example, chip 8 having die 6 with metallization layer 7. Pad 4 can be made of copper and metallization layer 7 can be made of nickel and gold. However, one can contemplate other materials in constructing these elements.

An electrical joint can be formed between metallization layer 2 and pad 4. In FIG. 1, conducting elements 4, 7 face each other at distance d1. In a first step, a viscous filler material is applied to first surface 1. The viscous filler material may have a micro-nano suspension in terms of carrier liquid 9 having dispersed microparticles 11 and necking particles 12. Microparticles 11 serve as spacer elements or spacer particles and define the minimum distance between first surface 1 and second surface 2, after assembly. For example, the viscous filler material may be dispensed onto first surface 1 by an extruder or syringe. Filler particles 11 and nanoparticles, or necking particles 12, may include electrically conductive material. For example, necking particles 12 may be made of copper or silver and spacer particles 11 may be made of a copper alloy.

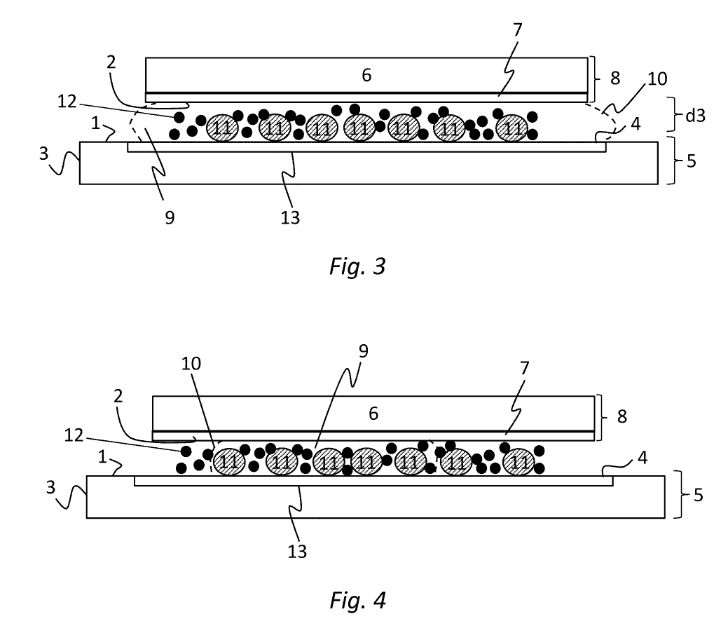

Next, first surface 1 and second surface 2 are brought together with each other as shown in FIG. 2. For example, in a production process, chip 8 is picked up and placed on top of pad 4 included in laminate 3 structure. By reducing distance d2 of the two opposite surfaces, first surface 1 and second surface 2, the viscous filler material or the suspension is deformed or squeezed away. When the distances are further reduced, as shown in FIG. 3, spacer particles 11 define distance d3 between the two surfaces, first surface 1 and second surface 2. The combination of carrier liquid 9, micro-particles 11 and necking particles 12 may be thought of as a suspension. The suspension is deformed as a consequence of the approaching of the two surfaces. While, as shown in FIG. 3, spacer particles 11 become attached to first surface 1 and second surface 2, necking particles 12 may still be dispersed in carrier fluid 9. Contact regions 13 are indicated where spacer particles 11 touch first surface 1 and second surface 2 and keep them at distance d3 apart. The dimensions of spacer particles 11 define the gap, width or height.

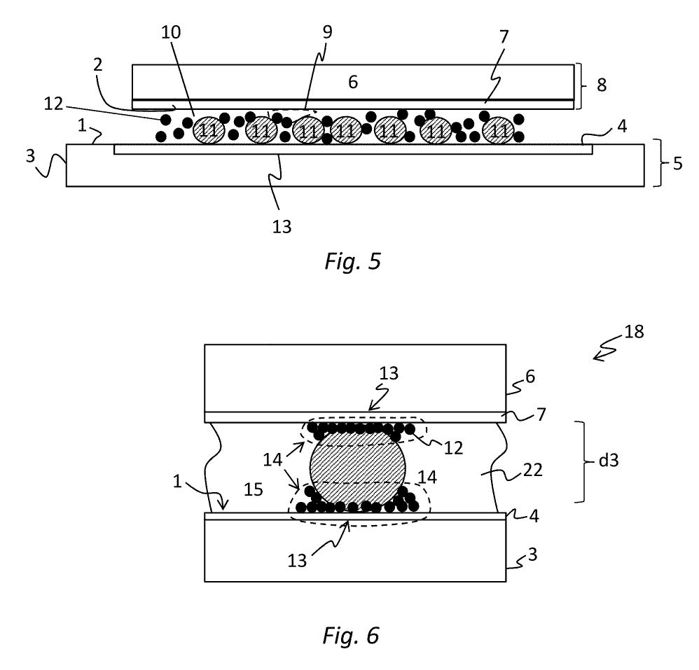

In a next step, carrier fluid 9 is removed from the gap by increasing the temperature. For example, the carrier fluid is evaporated. This is shown in FIG. 4. By evaporating carrier fluid 9, surface 10 of carrier fluid 9 shrinks. Due to the surface tension of carrier fluid 9, the lowest energy regions when a carrier fluid separates into droplets is in contact regions 13. As a result, necking particles 12 are transported to these locations and form neck-like structures as shown in the left and right spacer particles in FIG. 4. During the process of removing the carrier fluid by evaporation, necks are formed close to contact regions 13, as shown in FIG. 5, and potentially void regions 15 in the space between spacer particles 11.

FIG. 6 shows a detailed view of one spacer particle 11 that has an upper and a lower necking 14 close to contact regions 13 with first surface 1 or second surface 2, respectively. The necking provides improved electrical and thermal conductivity because many percolation paths reach through the electrically conducting nanoparticles from the electrically conducting spacer particle 11 to the respective surfaces, first surface 1 and second surface 2, of pad 4 and metallization layer 7. Optionally, a back-filling process is included, and as a result, resin 22 fills void regions 15. The resulting structure can be called stacked surface structure 18.

In an optional annealing step, the electrical joints between pad 4 and metallization layer 7 in terms of spacer particles 11 and necks 14 may be improved. As a result, a reliable electrical coupling is obtained. The annealing temperature can be around 150° C. which is still below a solder reflow temperature. One can contemplate the use of copper-type micro-particles as spacer particles 11 and also copper-comprising nanoparticles as necking particles 12. One can also contemplate the use of a mixture of nanoparticles so that necking particles 12 stick better to each other. Instead of dispersing the spacer particles in the carrier fluid, one can also contemplate the structuring of one of the two surfaces to include spacing means.

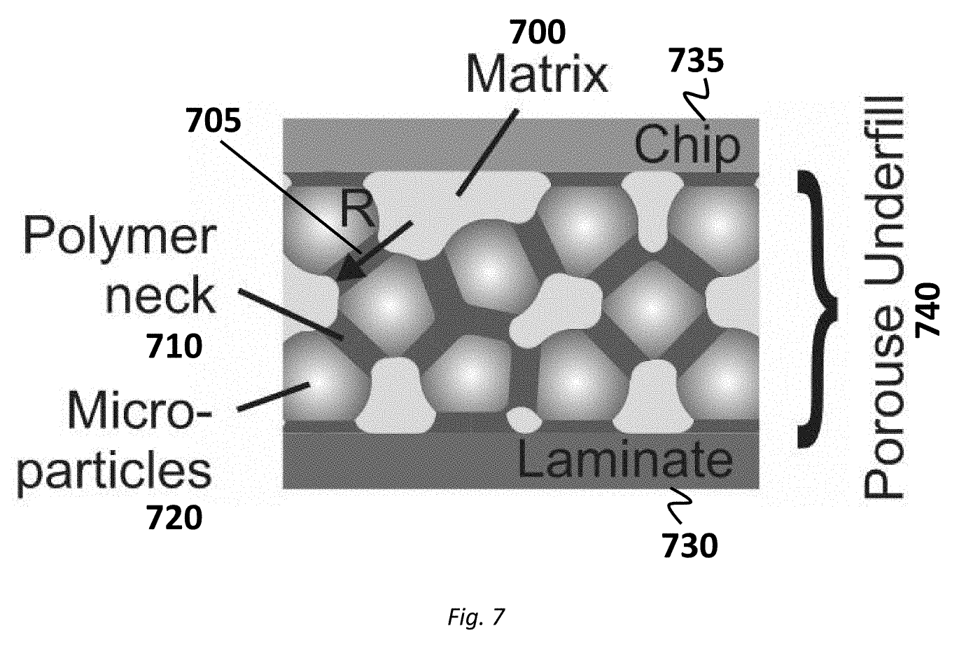

FIG. 7 schematically shows a porous underfill according to one embodiment of the disclosure. In FIG. 7, chip 735 and laminate 730 are separated by a gap that is filled with the porous underfill 740. The porous underfill 740 includes Resin 705, polymer matrix 700, polymer neck 710 and microparticles 720. In one embodiment, the microparticles can be silica, alumina, boron nitride, aluminum nitride or diamond.

There may be flexibility in formulating that is dictated by the end target. A first approach would be to deliver a filler quantity typical for a conventional underfill: 40 to 50 volume percent. The percent of resin could be on the order of 0.5 to 10 volume %. The balance may be solvent: 40 to 60 volume %. The back filling resin formulation can be a particle free formulation. A second approach is to deliver sufficient particles to help reinforce the necks only. These would typically be nanoparticles so a small percent is all that is needed. In this case, filler volume percent could be on the order of 0.5 to 5 percent. The percent resin on the order of 0.5 to 10% volume and the percent solvent is 85 to 99 percent. The back filling resin can be a more conventional underfill that has 50 to 60 volume percent filler particles.

An embodiment of the disclosure relates to the formulation of a temporary porous underfill by sequential filling method, including capillary bridging of a matrix material to secure the chip and electrical interconnects during test and burn-in while allowing the rework in failure cases. The rework may be implemented by shearing the die off the MCM at elevated temperature with acceptable shear forces. The shear forces may be determined as a function of the neck diameter. In another embodiment, the chip may be removed by dissolving the structural polymer necks by the injection of a solvent into the pores of a single die. The pores may allow the local access of the solvent to perform the dissolution steps in a short time period.

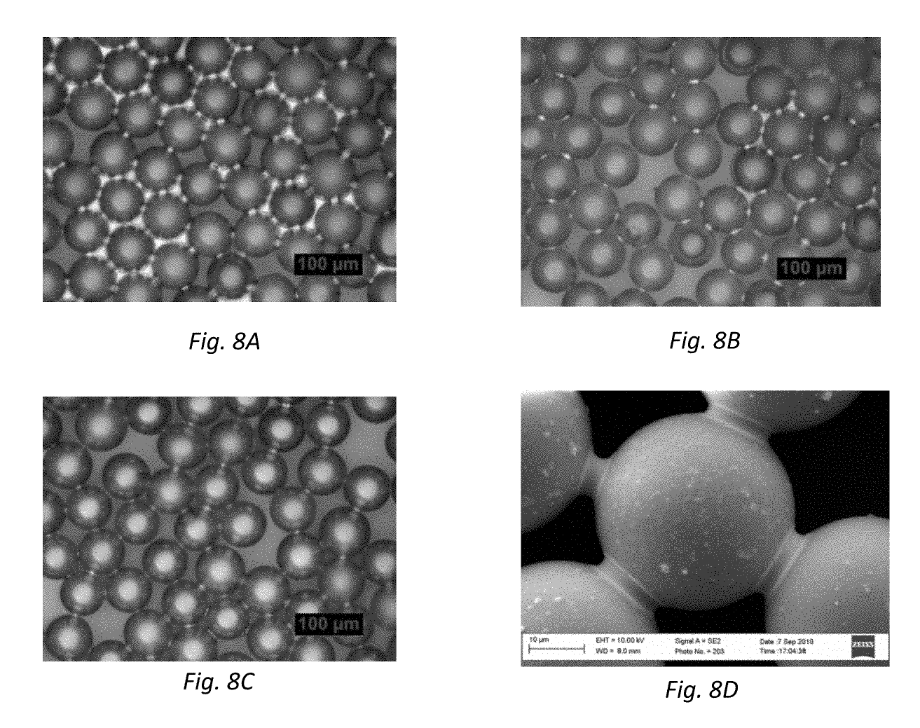

FIGS. 8A-8D show magnified compositions of polymer used for neck material according to one embodiment of the disclosure. As seen in FIGS. 8A-8D, the neck size and hence the pore size, surface area and mechanical strength of a porous underfill can be varied by the polymer content of the solution. FIGS. 8A-8D illustrate examples of silver (Ag) nanoparticle deposition.

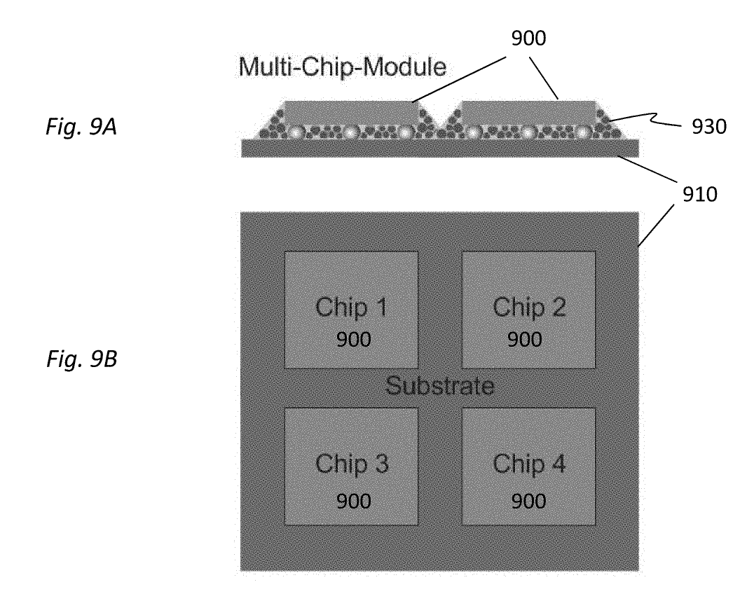

FIG. 9A schematically illustrates a side view of an exemplary MCM. FIG. 9B schematically illustrates a top view of an exemplary MCM. In FIGS. 9A and 9B, microchips 900 are arranged over substrate 910. Each microchip 900 is adhered to substrate 910 with a resin-polymer matrix as described herein. In one embodiment of the disclosure, the two surfaces need not form a microchip. The cavity may result from two surfaces; for example, a PCB and a chip or two chips.

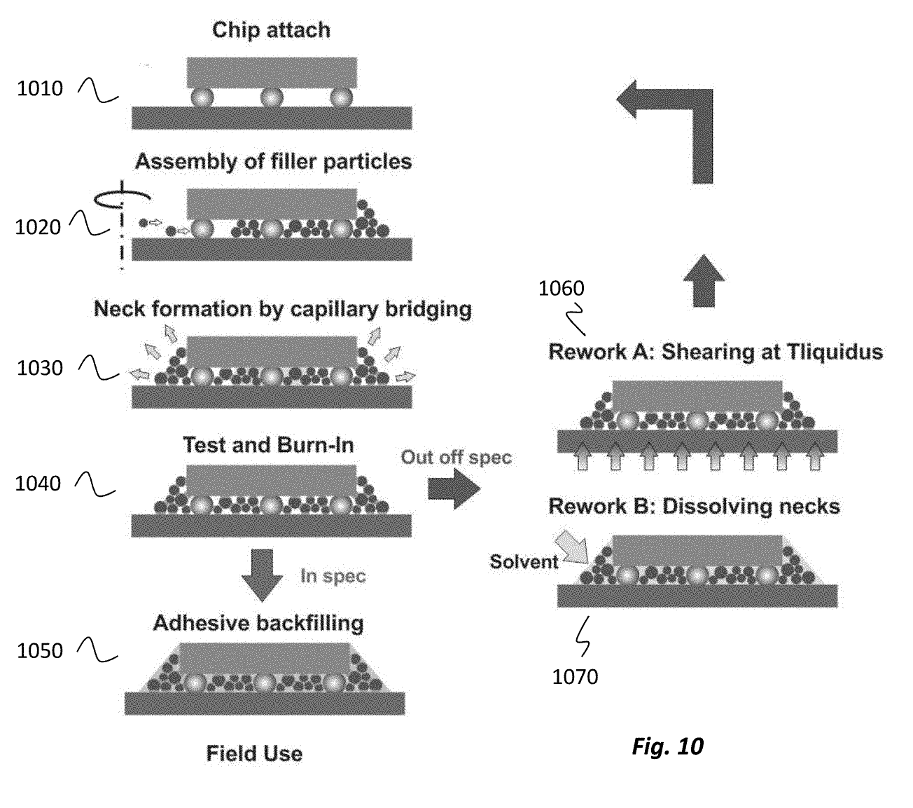

FIG. 10 schematically illustrates the process steps of an exemplary embodiment of the disclosure. In FIG. 10, a single die is shown as representative of multiple dies on an MCM. The process of FIG. 10 starts at step 1010 with the chip attachment. The chip may be attached by several solder balls as show in step 1010. At step 102, filler particles are introduced to spaces and gaps between the chip and the board. The composition of the filler particle may comprise the constituents described above. The microparticles may be silica, alumina, boron nitride, aluminum nitride or diamond.

At step 1030, neck formation is introduced by capillary bridging. This step may include, for example, removing solvent from the filler composition. At the end of this step, neck formation is complete and solderballs have necking material formed at the joints with the chip and the board. At step 1040 testing and burn-in of the microchip is done. If the chip is determined to be defective or out of specification, the chip may be removed according to the disclosed embodiment. For example, at step 1060, a rework solution including shearing at an elevated temperature is shown. Here, the temperature of the chip may be slightly elevated to loosen the neck material and enable removal of the defective microchip.

Step 1070 shows reworking through dissolving the neck with solvent. Here, solvent is introduced to loosen the bonds in the filler (and neck bridge) material. Once loose, the defective microchip may be removed. Once removed, cleaning techniques can be used to prepare the no-vacant site for a new chip attachment as shown in at step 1010. At the end of steps 1060 and 1070, a new microchip may be attached as replacement for the defective chip.

The replacement chip may be similarly adhered with capillary bridging and subsequently tested. If the original chip is not defective, or if a replacement chip survives the test and burn-in, then adhesive backfilling with final epoxy may be implemented as shown at step 1050.

In one embodiment of the disclosure, formulation of a porous underfill by capillary bridging between micron-sized filler particles may be done using a solution with dissolved polymer. In another embodiment, the polymer content may be in the range of about 0.1 to 1 vol % in the solution to vary the neck diameter to tailor the mechanical strength of the underfill. In another embodiment, the porous underfill may be applied to multiple chips on an MCM prior to test and burn-in. In still another embodiment, test and burn-in of the dies maybe performed on the MCM (i.e., as temporarily assembled microchips).

In still another embodiment, individual defective dies (microchips) can be reworked on the MCM by at least one of two methods. First, the dies may be sheared at an elevated temperature. The elevated temperature may be above the softening temperature of the neck polymer and solder liquids temperature. Second, a solvent may be dispensed into the pores to dissolve the necks. In still another embodiment, a replacement chip may be added to the MCM after preconditioning the joint site. If the MCM does not include a defective microchip, the pores of the porous underfill may be backfilled with a matrix material using capillary forces to achieve final mechanical strength required for field use.

While the principles of the disclosure have been illustrated in relation to the exemplary embodiments shown herein, the principles of the disclosure are not limited thereto and include any modification, variation or permutation thereof.

1. A method to form multi-chip module (MC) with porous underfill enabling rework, comprising the steps of:
attaching a plurality of microchips on to a substrate using a plurality of solderballs, the solderballs forming a plurality of gaps between the microchip and the substrate;
filling the plurality of gaps between the chip and the substrate with a porous composition comprising a slurry of polymer material, filler micro-particles, resin and solvent, wherein the step of filling the plurality of gaps is selected from one or more centrifugal-assisted filling, capillary or pre-apply;
substantially evaporating the solvent from the gaps at an evaporating solvent temperature;
for a first of the plurality of microchips, forming a mechanical neck by substantially evaporating the solvent from the gaps to form a capillary bridge, wherein the mechanical neck comprises phenoxy resin;
testing the first microchip to detect operation failure;
if operation failure detected, removing the first microchip with one of shearing the first microchip after localized heating of the first microchip or by chemically dissolving the mechanical neck between the first microchip and the substrate, reattaching a second microchip in the place of the first microchip after preparing the attachment site; and
if no operation failure is detected, adhesive backfilling the porous underfill using one or more epoxy adhesive having a final cure agent;
wherein the polymer material is selected from the group consisting of: polyimides, bismaleimides, epoxies and cyanate esters;
wherein the porous composition further comprises one or more of an epoxy and an initial cure agent requiring a higher cure temperature relative to the evaporating solvent temperature.
